(19) United States
(12) Patent Application Publication
(10) Pub. No.: US 2001/0015448 A1
(43) Pub. Date: Aug. 23, 2001

(54) Ferroelectric capacitor and semiconductor device

(76) Inventors: Takashi Kawakubo, Yokohama-shi (JP); Kenya Sano, Kawasaki-shi (JP); Ryoichi Ohara, Yokohama-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 09/749,788

(22) Filed: Dec. 28, 2000

(30) Foreign Application Priority Data
Dec. 28, 1999 (JP) 11-373063

(51) Int. Cl. H01L 27/108; H01L 29/00

(52) U.S. Cl. 257/296; 257/905; 257/532

(57) ABSTRACT

A ferroelectric capacitor comprising an Si substrate, a lower electrode including a metal film containing Ir or Rh and epitaxially grown on the Si substrate, and a conductive oxide film having a perovskite crystal structure and epitaxially grown on the metal film, a perovskite type ferroelectric thin film epitaxially grown on the lower electrode, and an upper electrode formed on the ferroelectric thin film. Alternatively, the lower electrode may be formed of a structure which comprises a silicide film represented by a chemical formula MSi₂ (wherein M is at least one kind of transition metal selected from nickel, cobalt and manganese) and epitaxially grown on the Si substrate, a metal film containing Ir or Rh and epitaxially grown on the silicide film, and a conductive oxide film having a perovskite crystal structure and epitaxially grown on the metal film.

### CROSS-REFERENCE TO RELATED APPLICATIONS

This application is based upon and claims the benefit of priority from the prior Japanese Patent Application No. 11-373063, filed Dec. 28, 1999, the entire contents of which are incorporated herein by reference.

### BACKGROUND OF THE INVENTION

The present invention relates to a ferroelectric capacitor and to a semiconductor memory device provided with the ferroelectric capacitor. In particular, the present invention relates to a ferroelectric capacitor having an improved lower electrode.

Recently, the development of a memory device (ferroelectric memory) using a ferroelectric capacitor comprising a ferroelectric thin film as a memory medium has been studied, and some of them are now actually utilized. This ferroelectric memory is of non-volatile type, having various advantages that an information stored therein would not be vanished even if power source is cut off, and that the inversion of spontaneous polarization is very rapid if the thickness of the ferroelectric thin film is sufficiently thin, so that a rapid writing and readout which are comparable to DRAM can be realized. Moreover, since a memory cell of one bit can be constituted by a single transistor and a single ferroelectric capacitor, the ferroelectric memory is suited for mass storage.

It is demanded for a ferroelectric thin film to exhibit a large remanent polarization and a low coercive electric field as well as a minimal temperature dependency of the remanent polarization, and to ensure the retention of remanent polarization for a long period of time in order to enable the ferroelectric thin film suitable for use as a ferroelectric memory.

As for the material to be used as a ferroelectric thin film, lead zirconate titanate (hereinafter, referred to as PZT) is mainly employed at present. This PZT is a solid solution of lead zirconate and lead titanate, a solid solution consisting of lead zirconate and lead titanate at a molar ratio of 1:1 being considered to be most excellent as a memory medium as it is large in spontaneous polarization and capable of inverting the polarization thereof at a low electric field. Additionally, since the transition temperature (Curie point) between the ferroelectric phase and paraelectric phase thereof is as high as 300° C. or more, there is little possibility that an information stored in the memory medium can be thermally vanished as long as the temperature to which the memory medium is exposed is confined within a temperature range (120° C. or less) in which an ordinary electronic circuit is generally operated.

However, it is well known in the art that the formation of thin PZT film of high quality is very difficult. A first reason for this is that lead which is a main component of PZT is more likely to be evaporated at a temperature of 500° C. or more, resulting in the difficulty of accurately controlling the composition of film to be formed. A second reason is the fact that, although this PZT exhibits ferroelectricity only when it is in the state of perovskite structure, a crystal structure called pyrochlore is more likely to be formed rather than the PZT having the perovskite structure. Additionally, when the PZT is applied to a silicon device, it is difficult to prevent lead constituting a main component of the PZT from being diffused into the silicon.

In addition to this PZT, barium titanate (BaTiO₃, hereinafter referred to simply as BTO) is also well known as a typical ferroelectric material. This BTO is known as having a perovskite structure just like PZT and a Curie temperature of about 120° C. Moreover, since Ba is less evaporable as compared with Pb, the control of composition in the formation of BTO thin film is comparatively easy. Further, there is little possibility in the crystalization of BTO that a different crystal structure other than perovskite structure can be formed.

In spite of these advantages of BTO, a capacitor employing a BTO thin film has not been so earnestly studied as being useful as a memory medium of ferroelectric memory. The reasons of this can be ascribed to a low remanent polarization of the BTO thin film as compared with PZT thin film and to the fact that the magnitude of remanent polarization of the BTO thin film depends greatly on temperature. The basic reason for this can be ascribed to the fact that the Curie temperature of BTO is comparatively low (120° C.). Therefore, if a ferroelectric memory is manufactured by making use of BTO, the resultant memory is accompanied with the problems that, if the ferroelectric memory is exposed to a high temperature of 120° C. or more, an information stored in the ferroelectric memory may be vanished, and that, since the temperature dependency of remanent polarization is relatively large even in a temperature range to which an electronic circuit is commonly exposed (85° C. or less), the operation of the ferroelectric memory may become unstable. Accordingly, a thin film capacitor employing a ferroelectric thin film consisting of BTO has been considered as being unsuitable for use as a memory medium of ferroelectric memory.

Meantime, it has been proposed by the present inventors to employ, as a novel ferroelectric thin film, a dielectric material (for example, BaₓSr₁₋ₓTiO₃, hereinafter referred to simply as BST) having a lattice constant which is relatively close to but slightly larger than the lattice constant of the lower electrode (for example, SrRuO₃, hereinafter referred to simply as SRO), and also to adopt a film-forming method which is relatively free from the generation of a misfit dislocation in the step of forming a film (i.e. RF magnetron sputtering method) in the epitaxial growth of a ferroelectric thin film on a single crystal substrate. As a result, it has been found out that due to the effect of this epitaxial growth, it is possible to retain a state wherein the lattice constant is extended in the thickness-wise direction (c-axis) and the lattice constant is shrunk in the in-plane direction (a-axis) as compared with the lattice constant which is inherent to the dielectric material (Japanese Patent No. 2878986, registered on Jan. 22, 1999).

As a result, it has been confirmed by the present inventors that it is possible to realize a ferroelectric thin film which is capable of shifting the ferroelectric Curie temperature to a higher temperature side, capable of exhibiting a large remanent polarization in the room temperature zone, and capable of retaining a sufficiently large remanent polarization even if the temperature is increased up to about 85° C.

For example, it has been confirmed by the present inventors through experiments (wherein an MgO single crystal substrate or an SrTiO₃ single-crystal substrate is employed as a substrate, the SRO (the lattice system is pseudo-cubic, the lattice constant being “a”=0.3930 as it is reduced to cubic) is employed as the lower electrode, and the BST having a composition region x=0.30-0.90 is employed as a dielectric substance) that it is possible to realize such practically preferable ferroelectric properties that a ferroelectricity can be developed even with a region of composition (x≦0.7) which has been considered as being inherently incapable of developing a ferroelectricity at room temperature, and that, as far as the composition region (x>0.7) which inherently exhibits a ferroelectricity at room temperature is concerned, the Curie temperature thereof which is inherently not less than room temperature can be further raised.

Namely, by making use of a BST ferroelectric capacitor whose c-axial length is artificially extended, it becomes possible to realize not only the chemically and thermally stable processing of BST but also an excellent ferroelectric property which is at least comparable with the PZT employing lead.

However, there is still a serious technical difficulty in the employment of the aforementioned technique for the manufacture of a non-volatile semiconductor memory of higher integration. Namely, if it is desired to further enhance the integration of memories, an epitaxial conductive film (the lower electrode) is required to be formed directly on the source/drain electrode of transistor or directly on the single crystal Si plug which has been formed on the source/drain electrode, which is followed by the formation of an epitaxial ferroelectric thin film on the epitaxial conductive film with the lattices of both films being substantially aligned with each other. However, the lower electrode thereof (a single layer or a multi-layer) is demanded to meet the following specifications.

(a) All of the layers are required to be electrically conductive.

(b) The Si-contact layer is required to epitaxially grow on an Si(100) plane, and the lower electrode in contact with a ferroelectric substance is required to have a lattice constant of 0.4 nm.

(c) On the occasion of growing a ferroelectric layer, the formation of insulating silicon oxide film due to the oxidation of the underlying Si layer should be prevented.

(d) On the occasion of fine-patterning at a submicron level after the deposition of the film of ferroelectric capacitor on the lower electrode, the strain introduced into the ferroelectric layer during the formation of the film should be prevented from being alleviated and hence the ferroelectricity should be prevented from being deteriorated.

(e) Even when a ferroelectric memory provided with a ferroelectric capacitor is operated after the fabrication thereof, the memory should be prevented from being suffered from any fatigue degradation due to the repetition of writing/reading.

As it is considered difficult to meet all of the aforementioned conditions if the underlying film is formed of a monolayer film, the present inventors have noticed the employment of a conductive film having a multi-layer film structure. For example, in order to enable a ferroelectric capacitor to withstand the fatigue failure, it is required to create a structure which is capable of preventing oxygen vacancy defects from being introduced into the surface of the ferroelectric layer by the effect of large electric field which will be generated on the occasion of writing/reading, more specifically, to create a structure where the ferroelectric layer is in contact with an oxide conductive electrode. However, if the surface of Si substrate is in contact with an oxide, the surface of Si substrate is inevitably oxidized in a subsequent step. Therefore, it is required that the lower electrode is formed of at least 2-ply structure comprising a non-oxide layer/a oxide layer.

As one example of such a lower electrode, the present inventors have developed a 3-ply conductive film consisting of a (Ti, Al) N layer/a Pt layer/an SRO layer, and then, a distorted epitaxial BTO ferroelectric thin film is deposited on this 3-ply conductive film, thereby confirming an excellent ferroelectricity with this solid film (IEEE Electric Device Letters, Vol. 18, No. 11, p. 529, 1997).

However, when the ferroelectric capacitor having this structure is finely patterned into a capacitor array of 20 nm square and then, the ferroelectricity thereof is measured, it was impossible to obtain a sufficient ferroelectricity. Further, when the lattice constant of the capacitor was measured by means of X-ray diffraction method and the results were studied, it was found that the strain that had been introduced into the BTO ferroelectric thin film by the fine patterning was alleviated due to the reduction of the value of c-axis of the BTO crystal. It was also found that the conductive film having the aforementioned structure was featured such that a swelling or peeling was more likely to be generated at the interface of the (Ti, Al) N layer/Pt layer due to a slight fluctuation of the film-forming condition of the ferroelectric thin film, thus resulting in a insufficient barrier property against the diffusion of oxygen into the Pt layer.

Any kinds of the prior art have failed to disclose a conductive film which is capable of meeting the aforementioned five conditions (a) to (e).

As explained above, according to the ferroelectric capacitor formed directly on an Si substrate, in particular, the ferroelectric capacitor whose ferroelectricity is strengthened by the epitaxial effect, it is difficult to overcome the aforementioned problems (a) to (e) which are expected to be raised when the capacitor is employed in a non-volatile memory of high integration.

### BRIEF SUMMARY OF THE INVENTION

Therefore, an object of the present invention is to provide a ferroelectric capacitor which is excellent in dielectric property and in reliability.

Another object of the present invention is to provide a semiconductor memory device which is provided with a ferroelectric capacitor which is excellent in dielectric property and in reliability.

According to the present invention, there is provided a ferroelectric capacitor comprising;

an Si substrate;

a lower electrode including a metal film containing Ir or Rh and epitaxially grown on the Si substrate, and a conductive oxide film having a perovskite crystal structure and epitaxially grown on the metal film;

a perovskite type ferroelectric thin film epitaxially grown on the lower electrode; and

an upper electrode formed on the ferroelectric thin film.

Further, according to the present invention, there is also provided a ferroelectric capacitor comprising;

an Si substrate;

a lower electrode including a silicide film represented by a chemical formula MSi₂ (wherein M is at least one kind of transition metal selected from the group consisting of nickel, cobalt and manganese) and epitaxially grown on the Si substrate, a metal film containing Ir or Rh and epitaxially grown on the silicide film, and a conductive oxide film having a perovskite crystal structure and epitaxially grown on the metal film;

a perovskite type ferroelectric thin film epitaxially grown on the lower electrode; and

an upper electrode formed on the ferroelectric thin film.

Additionally, according to the present invention, there is provided a semiconductor device comprising;

an Si substrate;

a MOS type transistor formed on the Si substrate; and

a ferroelectric capacitor formed on the Si substrate and connected with the MOS type transistor;

wherein the ferroelectric capacitor comprises;

a lower electrode including a metal film containing Ir or Rh and epitaxially grown on the Si substrate, and a conductive oxide film having a perovskite crystal structure and epitaxially grown on the metal film;

a perovskite type ferroelectric thin film epitaxially grown on the lower electrode; and

an upper electrode formed on the ferroelectric thin film.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

FIG. 1 is a cross-sectional view illustrating an element structure of the epitaxial capacitor according to Comparative Embodiment;

FIG. 2 is a graph showing a dimension dependency of the length of c-axis of BTO ferroelectric thin film in the epitaxial capacitor according to Comparative Embodiment, Embodiment 1 and Embodiment 2;

FIG. 3 is a cross-sectional view illustrating an element structure of the epitaxial capacitor according to Embodiment 1;

FIG. 4 is a cross-sectional view illustrating an element structure of the epitaxial capacitor according to Embodiment 2;

FIG. 5 is a cross-sectional view illustrating an element structure of the epitaxial capacitor according to Embodiment 3; and

FIGS. 6A to 6D illustrate respectively a cross-sectional view illustrating the manufacturing steps of an FRAM memory cell according to Embodiment 4 of the present invention.

### DETAILED DESCRIPTION OF THE INVENTION

The ferroelectric capacitor of the present invention can be represented by the following four aspects, i.e. a first, a second, a third and a fourth aspects.

According to the first aspect, the ferroelectric capacitor is constituted by a perovskite type ferroelectric thin film which is epitaxially grown through an lower electrode on a surface of Si substrate, and by an upper electrode which is formed on the ferroelectric thin film, and is characterized in that the lower electrode is formed of a 2-ply epitaxial film comprising a metal film containing Ir or Rh and formed on the Si substrate, and a conductive oxide film having a perovskite crystal structure and formed on the metal film.

According to the second aspect, the ferroelectric capacitor is constituted by a perovskite type ferroelectric thin film which is epitaxially grown through an lower electrode on a surface of Si substrate, and by an upper electrode which is formed on the ferroelectric thin film, and is characterized in that the lower electrode is formed of a 3-ply epitaxial film comprising a nitride film formed on the Si substrate, a metal film containing Ir or Rh and formed on the nitride film, and a conductive oxide film having a perovskite crystal structure and formed on the metal film.

According to the third aspect, the ferroelectric capacitor is constituted by a perovskite type ferroelectric thin film which is epitaxially grown through an lower electrode on a surface of Si substrate, and by an upper electrode which is formed on the ferroelectric thin film, and is characterized in that the lower electrode is formed of a 4-ply epitaxial film comprising a silicide film represented by a chemical formula MSi₂ (wherein M is at least one kind of transition metal selected from the group consisting of nickel, cobalt and manganese) and formed on the Si substrate, a nitride film formed on the silicide film, a metal film containing Ir or Rh and formed on the nitride film, and a conductive oxide film having a perovskite crystal structure and formed on the metal film.

According to the fourth aspect, the ferroelectric capacitor is constituted by a perovskite type ferroelectric thin film which is epitaxially grown through an lower electrode on a surface of Si substrate, and by an upper electrode which is formed on the ferroelectric thin film, and is characterized in that the lower electrode is formed of a 3-ply epitaxial film comprising a silicide film represented by a chemical formula MSi₂ (wherein M is at least one kind of transition metal selected from the group consisting of nickel, cobalt and manganese) and formed on the Si substrate, a metal film containing Ir or Rh and formed on the silicide film, and a conductive oxide film having a perovskite crystal structure and formed on the metal film.

Furthermore, there are the following preferable specific aspects.

(1) The ferroelectric thin film is featured in that the length Ce of c-axis after an epitaxial growth and the length Co of c-axis inherent to the tetragonal system or of a-axis inherent to the cubic system before the epitaxial growth and corresponding to said c-axis Ce meet the following formula:

Ce/Co≧1.02.

(2) The nitride film is formed of TiN or a substituted TiN wherein part of Ti is substituted by at least one kind of metals selected from the group consisting of Al, V, Mo, Nb and Ta.

(3) The metal film comprising Ir is formed of an alloy having an fcc structure, wherein part of Ir is substituted by at least one kind of metals selected from the group consisting of Re, Ru, Os, Pt, Pd and Rh.

(4) The metal film comprising Rh is formed of an alloy having an fcc structure, wherein part of Rh is substituted by at least one kind of metals selected from the group consisting of Re, Ru, Os, Pt, Pd and Ir.

(5) The perovskite type conductive oxide film is formed of an oxide represented by a general formula ABO_{3-δ} (δ is 0≦δ<1), wherein A is at least one kind selected from the group consisting of alkaline earth metals, rare earth metals and vacancy defect, and B is a transition metal.

(6) The ferroelectric thin film is formed of a perovskite crystal structure represented by a chemical formula ABO₃, wherein A is at least one kind selected from the group consisting of Ba, Sr and Ca, and B is at least one kind selected from the group consisting of Ti, Zr, Hf and Sn.

(7) The lower electrode and the ferroelectric thin film are epitaxially grown on the Si(100) substrate.

(8) The film thickness of each of the thin films constituting the lower electrode is confined to such that the conductive oxide film has a thickness ranging from 10 to 50 nm, the metal film has a thickness ranging from 10 to 50 nm, the nitride film has a thickness ranging from 5 to 30 nm, and the silicide (MSi₂) film has a thickness ranging from 5 to 30.

The ferroelectric capacitor according to the present invention is characterized in that a capacitor employing a ferroelectric thin film where a strain introduced during the epitaxial growth thereof is taken advantage of is fabricated on a Si substrate in a manner to ensure an excellent quality of the film, and that an excellent ferroelectric property is enabled to be retained without alleviating the strain even after the fine patterning of the film at a micron level.

Further, since the lower electrode to be employed in the present invention is excellent in adhesivity with an underlayer such as an Si substrate, it is possible to obtain a highly reliable ferroelectric capacitor which can be hardly peeled from the Si substrate.

It is also possible to fabricate a ferroelectric memory of ultra-high integration and of high reliability by integrationally forming the ferroelectric capacitors of the present invention and transistors at a high density on an Si substrate.

Next, the basic principle of the present invention will be explained prior to the explanation of the embodiments of the present invention.

With a view to attain the aforementioned objects, the present inventors have studied on various combinations of conductive films. As a result, it was found to be imperative that the capacitor is provided with a 2-ply conductive structure as set forth in the aforementioned first aspect.

The ferroelectric capacitor according to the first aspect of the present invention will be explained in detail as follows.

First of all, the electrode to be contacted with a ferroelectric substance will be discussed. In the case of the capacitor where a perovskite oxide ferroelectric substance is employed as a dielectric layer, when an operating voltage is repeatedly applied thereto, oxygen vacancy defects are caused to be formed in the ferroelectric substance, thereby deteriorating the ferroelectricity of the capacitor. Therefore, in order to prevent this deterioration of ferroelectricity, it is required to employ an oxide electrode as an electrode. Among oxide electrodes, an electrode consisting of a perovskite conductive oxide and having the same crystal structure as that of the ferroelectric substance is required to be employed.

As for the perovskite conductive oxide mentioned above, (Ba, Sr, Ca)RuO₃, (Ba, Sr, Ca)MoO₃ or (Ba, Sr, ca)TiO₃ doped with Nb or La can be typically employed. In particular, a perovskite conductive oxide (electrode) whose lattice constant is slightly smaller than the lattice constant of the ferroelectric crystal should be selected, and then, both of the ferroelectric substance and the electrode are allowed to epitaxially grow, thereby causing the lattice of ferroelectric substance to be distorted in the direction perpendicular to the surface of the film, thus making it possible to artificially enhancing the ferroelectricity (Japanese Patent Publication No. 2878986 described above). As for the quantity of strain in this case, it should preferably be 2% or more. One example of the combination of such conductive films is a combination of an SrTiO₃ electrode and a BST dielectric substance.

Problems in this case are how to connect the oxide electrode with the surface of the barrier layer formed of Si, a silicide or a nitride. Namely, it is desired to epitaxially grow the oxide electrode with excellent crystallinity, as in the case where a Pt intermediate layer is employed, without alleviating the strain of the ferroelectric thin film formed on the barrier layer through fine patterning and also without oxidizing the underlying barrier layer.

Most simple method would be a method of forming the oxide electrode directly on the surface of the barrier layer. As a result of repeated studies made by the present inventors through experiments and theory, it has been found possible to enable both barrier layer and oxide electrode to epitaxially grow if (Ti, Al)N is employed as the barrier layer exhibiting most excellent oxidation resistance, and also if a Nb-doped SrTiO₃ electrode which is thermodynamically stable is employed as the oxide electrode. However, it was found out, through the observation of a section of films by making use of a microscope or through the evaluation of the electric property of the ferroelectric capacitor after the formation of the films of ferroelectric capacitor, that even though the epitaxial growth thereof was recognized, the interface of the (Ti, Al)N barrier layer was caused to oxidize thus producing the oxides of Ti and Al during a subsequent step of growing the oxide electrode or oxide dielectrics, thereby forming an electrically high resistant layer.

Therefore, it is imperative to interpose a metal layer acting as a barrier against the oxidation between the barrier layer and the oxide layer. In the aforementioned method (IEEE Electric Device Letters, Vol. 18, No. 11, p. 529, 1997), Pt was employed as the metal layer. However, when the capacitor and the conductive layer are subjected to a fine patterning of micron level, the Pt layer is plastically deformed due to the stress imposed on the capacitor, thereby raising the problem that the stress applied to the capacitor is alleviated.

Under the circumstances, the present inventors have made an extensive study to find a metal substituting for Pt. As a result, it has been found out that an alloy comprising Ir or Rh and having the fcc structure is most suited for use in this case because of the following reasons.

(i) Both Ir and Rh are a stable noble metal which can be hardly oxidized.

(ii) Even if Ir and Rh are oxidized, the oxides thereof are electrically conductive.

(iii) The Vickers hardness of Ir and Rh is: 200 to 650 for Ir and 120 to 300 for Rh. Namely, in contrast to Pt whose Vickers hardness is in the range of 40 to 100, i.e. relatively soft, both Ir and Rh are very hard and hardly deformable, so that even if they are subjected to a fine patterning of micron level, the alleviation of stress due to the plastic deformation would be hardly occurred.

(iv) Ir and Rh are both cubic system. The lattice constant of Ir is 0.3839 nm, while the lattice constant of Rh is 0.3803 nm, both being close to the lattice constant 0.421 nm of TiN and to the lattice constant 0.39 nm of the perovskite oxide electrode. Further, both Ir and Rh can be epitaxially grown.

In this case, part of Ir or Rh may be substituted by at least one kind of metal selected from the group consisting of Re, Ru, Os, Pt, Pd, Rh and Ir. It is expected that if part of Ir or Rh is substituted by the aforementioned metal or metals, the hardness of the resultant alloys can be further increased due to a phenomenon called solid solution hardening, thus making the alloys hardly deformable.

When these substituted metals are oxidized, the resultant oxides would be also electrically conductive. However, the crystal structure of the substituted metals is required to be fcc, and the degree of substitution should preferably be confined to not more than about 20%.

As explained above, only when a lower electrode of 2-ply structure which is formed through a successive epitaxial growth of an alloy comprising Ir or Rh and of perovskite type oxide electrode is employed, it becomes possible to satisfy all of the aforementioned specifications (a) to (e) and to manufacture an epitaxial ferroelectric capacitor which is optimum as a semiconductor memory.

By the way, although the first aspect of the present invention has been explained mainly with respect to the strained epitaxial ferroelectric capacitor, it should not be construed that the present invention is effective only to the strained epitaxial ferroelectric capacitor. As a matter of fact, it is needless to say that the present invention can be valuably utilized not only for all of the epitaxial capacitors but also for all of the polycrystalline capacitors.

Next, the present inventors have further intensively studied on the 2-ply structure consisting of an Ir of Rh metal layer and an oxide conductive layer, which is employed in the aforementioned first aspect, as well as on the conductive barrier to be interposed between this 2-ply structure and the Si substrate. As a result, the structures according to the aforementioned second to fourth aspects are also found useful.

In the second aspect of the present invention, a nitride is optimum, as described above, as a conductive layer to be contacted with Si and having a barrier effect against interdiffusion between Si and metal. In particular, TiN is suited for use, because it can be epitaxially grown on Si(100) plane and most excellent in oxidation resistance among nitrides. Further, if part of Ti is substituted by at least one kind of metals selected from the group consisting of Al, V, Mo, Nb and Ta, the oxidation resistance of the resultant nitrides can be further enhanced and at the same time, the matching thereof with the Si substrate would be improved, thereby improving the crystallinity of the nitrides. As for the degree of substitution, it should be selected within a range which enables the substituent to form a solid solution with TiN and which would not deteriorate the crystallinity of the nitride, i.e. preferably at most 20%.

The third aspect of the present invention is aimed at solving the problem of how to form an epitaxial conductive layer of high-film quality as a first layer on a Si substrate for the purpose of fabricating a perovskite epitaxial capacitor exhibiting an excellent dielectric property on the Si substrate, which is a main object of the present invention. Therefore, this third aspect is featured in that a silicide layer having a lattice constant which is substantially identical with the lattice constant of Si(100) plane is epitaxially grown at first, and then, a nitride having a different lattice constant from that of silicide layer is epitaxially grown.

Since Si constituting a semiconductor has a bonding directionality and a bonding hand called a dangling bond on the surface thereof, so that the interface of Si is very sensitive to lattice matching. Therefore, when a material whose lattice constant is not well aligned with the lattice constant of Si is to be formed on a Si substrate, it would be difficult to grow a film exhibiting an excellent crystallinity even if the epitaxial growth thereof is allowed to occur. Because, some of bonding hands of Si may become superfluous depending on the degree of the mismatching of lattice, thereby generating a dislocation of large energy at the interface and hence disturbing the crystallinity of epitaxial layer.

For example, when an epitaxial film of TiN (lattice constant: 0.423 nm) is formed on a Si substrate, the dislocation can be observed at a ratio of approximately one dislocation per three lattices of Si at the interface between the epitaxial film and the Si substrate, so that even if the epitaxial growth is performed at an optimum condition by means of a sputtering method or a laser ablation deposition method, it is very difficult to confine the half width of the rocking curve to less than 1° in the XRD measurement which is one of the characteristics representing the disturbance of crystallinity.

Meanwhile, it is known that some of metal suicides have a lattice constant which is approximately identical with that of Si, and are capable of forming a high-quality epitaxial film. Following Table 1 shows examples of silicide which are capable of forming an epitaxial film.

TABLE 1

| Orientation of | | | | Melting point |
|---|---|---|---|---|
| Si substrate | Silicide | Structure | Mismatch (%) | (° C.) |
| (100) | NiSi₂ | Cubic system (CaF₂) | 0.4 | 993 |
| | CoSi₂ | Cubic system (CaF₂) | 1.2 | 1326 |
| | MnSi₂ | Tetragonal system | 1.5 | 1150 |

It becomes possible, through the employment of these silicides, to fabricate a very flat epitaxial film on an Si substrate, the epitaxial film being very excellent in film quality and 0.1° or less in half width of the rocking curve.

Once an epitaxial film of excellent film quality can be formed on a Si substrate in this manner, it becomes possible to form thereon any other epitaxial metal films having a different lattice constant while ensuring an excellent film quality thereof. The reason for this is that since there is no directionality in bonding in the case of metallic bonding, and furthermore, since the interface is far more flat than semiconductor in electronic view point, the energy of interfacial dislocation is very small. Therefore, as compared with the bonding between a semiconductor and a metal, it is possible in case of the bonding between a metal and a metal that even if there is a mismatching of lattice constant, an epitaxial film having a far excellent film quality can be formed. As for the materials which can be epitaxially grown on a silicide layer and is capable of withstanding an oxidizing atmosphere on the occasion of forming an oxide-based epitaxial capacitor, it is possible to employ a nitride such as TiN.

Another advantage of employing an Si/epitaxial silicide/epitaxial nitride film structure instead of employing an Si/epitaxial nitride film structure is that the contact resistance thereof to the Si substrate can be extremely minimized due to the fact that the height of Schottky barrier between Si and silicide becomes smaller.

By the way, as for the method of forming an epitaxial silicide film, several methods are known. As for the film-forming method which is most suited for forming an Si (100)/CoSi₂, it is preferable to employ a method wherein only Co or both Co and Si are fed by means of sputtering, thermal vapor deposition or laser ablation deposition to a Si substrate heated to a temperature of about 500° C. for instance to thereby allow a reaction to proceed at a small film-forming rate, thus forming an epitaxial silicide film. Further, as for the film-forming method which is most suited for forming an Si (100)/NiSi₂, it is preferable to employ a method wherein Ni and Si are deposited to several nanometers by means of sputtering, thermal vapor deposition or laser vapor deposition on a Si substrate at room temperature, and then, the substrate is heated to thereby allow a reaction to proceed, thus forming an epitaxial silicide film.

The fourth aspect of the present invention is featured in that a silicide film having almost the same lattice constant as that of the Si(100) plane is epitaxially grown at first, and then, a metal layer comprising Ir or Rh according to the first aspect is directly epitaxially grown on the silicide film. There is a difference of about 30% in lattice constant between the values of NiSi₂ and CoSi₂ and the values of Ir and Rh. However, as shown in the following Table 2, when the lattice constant of NiSi₂ and CoSi₂ is multiplied by 1/\sqrt{2}, it can be made identical with the lattice constant of Ir and Rh. Namely, when the lattice of Ir or Rh is rotated in-plane by an angle of 45°, the lattice of them can be matched with each other as represented by the orientational relationship of: NiSi₂(001)//Ir(001) or NiSi₂<110>//Ir<100>.

TABLE 2

| | | Lattice constant | Lattice |
|---|---|---|---|
| Crystal | Structure | (nm) | constant /√2 |
| NiSi₂ | Cubic system (CaF₂) | 0.541 | 0.383 |
| CoSi₂ | Cubic system (CaF₂) | 0.538 | 0.380 |
| Ir | Tetragonal system (fcc) | 0.384 | |
| Rh | Tetragonal system (fcc) | 0.380 | |

As explained above, it is possible, through the employment of silicides of Ni or Co, to epitaxially grow them with a lattice relationship of 1:1 with respect to Si. With respect to Ir and Rh which will be deposited thereon, they can be epitaxially grown with a lattice relationship of \sqrt{2}:1, so that it would become possible to laminate a very flat epitaxial film on an Si substrate, while ensuring very high excellency in film quality, e.g. 0.1° or less in half width of the rocking curve.

However, since the oxidation resistance of the silicide film is not so high, the fabrication of upper and lower electrodes and dielectric films both constituting a capacitor should preferably be performed in an oxygen-free Ar atmosphere with the temperature of substrate being kept at as low temperature as possible.

As for the conductive perovskite electrode that can be formed into a film in an oxygen-free atmosphere, an oxide electrode composed of SrTiO₃ which is partially substituted by Nb or La can be employed.

As for the dielectric material of perovskite structure to be employed in the above first to fourth aspects, it is possible to employ a composition represented by ABO₃ wherein A is mainly constituted by Ba, and part of Ba is substituted by at least one kind of elements selected from Sr and Ca. Further, B may be selected from Ti, Sn, Zr, Hf, a solid solution thereof. Alternatively, B may be selected from composite oxides such as Mg_{⅓}, Ta_{⅔}, Nb_{⅔}, Zn_{⅓}, Nb_{⅔}, Zn_{⅔} and Ta_{⅔}, or a solid solution thereof.

As for the material for the perovskite type conductive oxide to be employed in the first to fourth aspects of the present invention, it is possible to employ strontium ruthenate, strontium molybdate, a substituted strontium titanate which is partially substituted by niobium or lanthanum.

Next, the embodiments of the present invention and comparative embodiment will be explained with reference to the drawings.

(Comparative Embodiment)

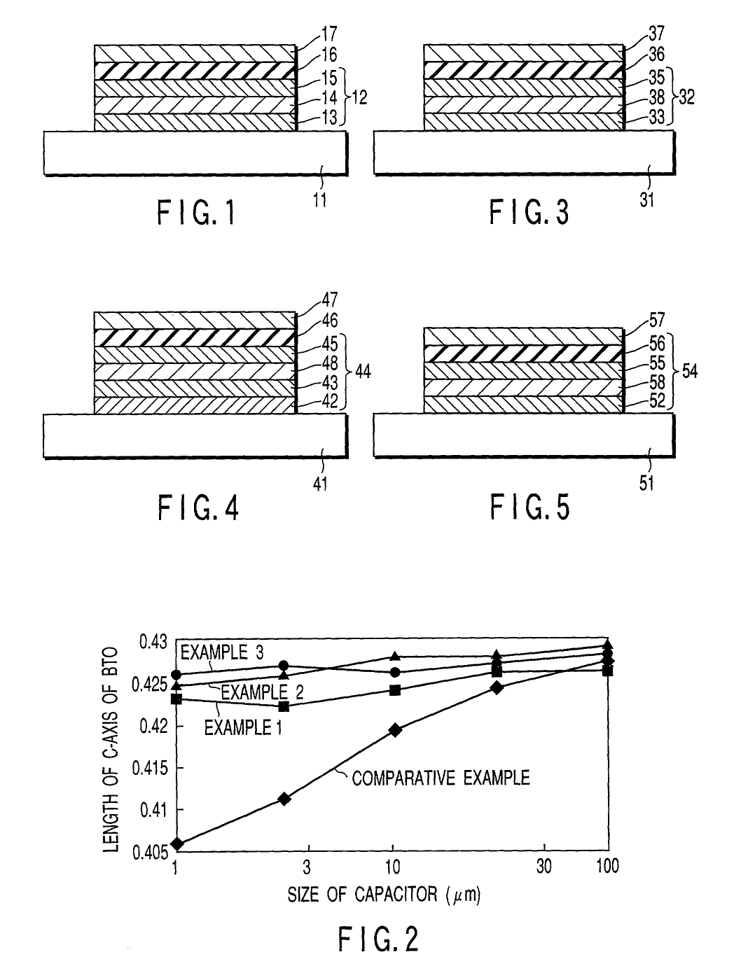

FIG. 1 shows a cross-sectional view illustrating a device structure of the epitaxial capacitor representing a comparative embodiment.

Referring first to FIG. 1, a (TiO_{0.9}Al_{0.1})N barrier layer 13 (cubic system: lattice constant 0.423 nm), a Pt layer 14 (cubic system: lattice constant 0.392 nm), and an SRO layer 15 (pseudo-cubic system: lattice constant 0.391 nm) were epitaxially grown in the mentioned order on the surface of a Si(100) substrate 11 (lattice constant 0.543 nm) by means of an RF magnetron sputtering method at a temperature of 600° C., thereby forming a lower electrode 12. Thereafter, under the same conditions as mentioned above, a BTO ferroelectric thin film 16 (tetragonal system: a-axis lattice constant 0.399 nm; c-axis lattice constant 0.403 nm) and an SRO upper electrode 17 were epitaxially grown.

By the way, the epitaxial growth of the (Ti, Al)N was performed using a Ti/Al alloy target in an Ar/N₂ atmosphere. The epitaxial growth of the Pt was performed using a Pt target in an Ar atmosphere. The epitaxial growth of both of SRO and BTO was respectively performed using an oxide target in an Ar/O₂ atmosphere (Ar:O₂=4:1).

By means of X-ray diffraction, it was confirmed that these (Ti, Al)N layer 13, Pt layer 14, SRO layer 15 and BTO layer 16 were all epitaxially grown at the (001) orientation relative to the surface of substrate. The length of c-axis of the BTO layer 16 was 0.427 nm which was about 6% longer than the length of c-axis of bulk BTO crystal. Further, when the half width was measured by measuring the rocking curve of the (002) peak of each layer thus grown, the half width in the case of the (Ti, Al)N 13 was 1.2°, the half width in the case of the Pt layer 14 was 1.00, the half width in the case of the SRO layer 15 was 1.4°, and the half width in the case of the BTO layer 16 was 1.5°.

Next, this laminated layer was patterned by means of lithography and dry etching techniques until the etching was proceeded up to the Si substrate, thereby forming capacitors having sizes ranging from 1 μm square to 100 μm square. When the length of c-axis of the BTO layer 16 was measured, the length of c-axis was remarkably reduced due to the alleviation of the strain as the size of the capacitor became smaller, i.e. the length of c-axis at 1 μm square was almost the same as that of bulk crystal.

As explained above, the capacitor having an Si/(Ti, Al)N/Pt/SRO/BTO/SRO structure shown in FIG. 1 is accompanied with a problem that if the size of capacitor is miniaturized, the strain that has been introduced into the BTO capacitor is alleviated.

(Embodiment 1)

FIG. 3 shows a cross-sectional view illustrating a device structure of the epitaxial capacitor according to the first embodiment.

Referring first to FIG. 3, a (TiO_{0.9}Al_{0.1})N barrier layer 33 (cubic system: lattice constant 0.423 nm), an Ir layer 38 (cubic system: lattice constant 0.384 nm), and an SRO layer 35 (pseudo-cubic system: lattice constant 0.391 nm) were epitaxially grown in the mentioned order on the surface of a Si(100) substrate 31 (lattice constant 0.543 nm) by means of an RF magnetron sputtering method at a temperature of 600° C., thereby forming a lower electrode 32. Thereafter, under the same conditions as mentioned above, a BTO ferroelectric thin film 36 (tetragonal system: a-axis lattice constant 0.399 nm; c-axis lattice constant 0.403 nm) and an SRO upper electrode 37 were epitaxially grown.

By the way, the epitaxial growth of the (Ti, Al)N was performed using a Ti/Al alloy target in an Ar/N₂ atmosphere. The epitaxial growth of the Ir was performed using an Ir target in an Ar atmosphere. The epitaxial growth of both of SRO and BTO was respectively performed using an oxide target in an Ar/O₂ atmosphere (Ar:O₂=4:1).

By means of X-ray diffraction, it was confirmed that these (Ti, Al)N layer 33, Ir layer 38, SRO layer 35 and BTO layer 36 were all epitaxially grown at the (001) orientation relative to the surface of substrate. The length of c-axis of the BTO layer 36 was 0.426 nm which was about 6% longer than the length of c-axis of bulk BTO crystal, and was almost the same as where Pt was employed. Further, when the half width was measured by measuring the rocking curve of the (002) peak of each layer thus grown, the half width in the case of the (Ti, Al)N layer 33 was 1.20, the half width in the case of the Ir layer 38 was 1.20, the half width in the case of the SRO layer 35 was 1.50, and the half width in the case of the BTO layer 36 was 1.6°.

Next, this laminated layer was patterned by means of lithography and dry etching techniques until the etching was proceeded up to the Si substrate, thereby forming capacitors having sizes ranging from 1 μm square to 100 μm square. When the length of c-axis of the BTO layer 36 was measured, the reduction in the length of c-axis due to the alleviation of the strain where the size of the capacitor was reduced, was found minimal as shown in FIG. 2, i.e. the length was 0.423 even when the size was 1 μm square, indicating that the length of c-axis was sufficiently extended as compared with the value of bulk crystal. Namely, the length Ce of c-axis after an epitaxial growth of BTO and the length Co of c-axis inherent to the tetragonal system before the epitaxial growth and corresponding to the c-axis Ce were found to meet the formula: Ce/Co≧1.02.

As explained above, in the structure of the capacitor having an Si/(Ti, Al)N/Ir/SRO/BTO/SRO structure, it is possible, even if the size of capacitor is miniaturized, to expect a sufficiently excellent ferroelectric property without alleviating the strain that has been introduced into the BTO capacitor.

(Embodiment 2)

FIG. 4 shows a cross-sectional view illustrating an element structure of the epitaxial capacitor according to the second embodiment.

Referring first to FIG. 4, a CoSi₂ layer 42 (cubic system: lattice constant 0.5376 nm), a (Ti_{0.9}Al_{0.1})N barrier layer 43 (cubic system: lattice constant 0.423 nm), an Ir layer 48 (cubic system: lattice constant 0.384 nm), and an SRO layer 45 (pseudo-cubic system: lattice constant 0.391 nm) were epitaxially grown in the mentioned order on the surface of a Si(100) substrate 41 (lattice constant 0.543 nm) by means of an RF magnetron sputtering method at a temperature of 600° C., thereby forming a lower electrode 44.

Thereafter, under the same conditions as mentioned above, a BTO ferroelectric thin film 46 (tetragonal system: a-axis lattice constant 0.399 nm; c-axis lattice constant 0.403 nm) and an SRO upper electrode 47 were epitaxially grown. The growth of all of the layers except the CoSi₂ layer 42 was performed in the same manner as in Embodiment 1. By making use of a Co target, Co was fed at a rate of 0.01 nm/s in an Ar atmosphere, thereby allowing Co to react with the Si substrate to thereby form an epitaxial CoSi₂ layer.

By means of X-ray diffraction, it was confirmed that these CoSi₂ layer 42, (Ti, Al)N layer 43, Ir layer 48, SRO layer 45 and BTO layer 46 were all epitaxially grown at the (001) orientation relative to the surface of substrate. The length of c-axis of the BTO layer 46 was 0.429 nm which was about 7% longer than the length of c-axis of bulk BTO crystal, indicating that the length of c-axis was further elongated as compared with Embodiment 1 where the CoSi₂ layer 42 was not employed. Further, when the half width was measured by measuring the rocking curve of the (002) peak of each layer thus grown, the half width in the case of the CoSi₂ layer 42 was 0.20, the half width in the case of the (Ti, Al)N layer 43 was 0.40, the half width in the case of the Ir layer 48 was 0.50, the half width in the case of the SRO layer 45 was 0.7°, and the half width in the case of the BTO layer 46 was 0.7°, indicating that the crystallinity was greatly improved as compared with Embodiment 1 where the CoSi₂ layer was not employed.

Next, this laminated layer was patterned by means of lithography and dry etching techniques until the etching was proceeded up to the Si substrate, thereby forming capacitors having sizes ranging from 1 μm square to 100 μm square. When the length of c-axis of the BTO layer 46 was measured, the reduction in the length of c-axis due to the alleviation of the strain where the size of the capacitor was reduced, was found minimal as shown in FIG. 2, i.e. the length was 0.425 even when the size was 1 μm square, indicating that the length of c-axis was sufficiently extended as compared with the value of bulk crystal.

As explained above, in the structure of the capacitor which was manufactured by directly forming a CoSi₂ film, i.e. a film of lattice matching type metal on an Si substrate constituted by a semiconductor, thus forming an epitaxial film of excellent crystallinity, and then, a (Ti, Al)N/Ir/SRO/BTO/SRO structure is laminated on the epitaxial film, it is possible to obtain a dielectric film of excellent crystallinity, and also to expect, even if the size of capacitor is miniaturized, a sufficiently excellent ferroelectric property without alleviating the strain that has been introduced into the BTO capacitor.

(Embodiment 3)

FIG. 5 shows a cross-sectional view illustrating an element structure of the epitaxial capacitor according to the third embodiment.

First of all, an NiSi₂ layer 52 (cubic system: lattice constant 0.541 nm) was grown to a thickness of 3 nm on the surface of a Si(100) substrate 51 (lattice constant 0.543 nm) by means of an RF magnetron sputtering method at room temperature, and then, the temperature was raised up to 600° C., thereby epitaxializing the NiSi₂ layer 52. Thereafter, a Rh layer 58 (cubic system: lattice constant 0.380 nm) was epitaxially grown in the same manner as described above by means of an RF magnetron sputtering method at a temperature of 600° C. in an Ar atmosphere. Then, an Sr(Ti_{0.8}Nb_{0.2})O₃ layer 55 (cubic system: lattice constant 0.393 nm), a BTO ferroelectric thin film 56 (tetragonal system: a-axis lattice constant 0.399 nm; c-axis lattice constant 0.403 nm), and an Sr(Ti_{0.8}Nb_{0.2})O₃ upper electrode 57 were likewise epitaxially grown in the mentioned order on the surface of Rh layer 58 by means of an RF magnetron sputtering method at a temperature of 550° C. In this case, a lower electrode 54 was constituted by the 3-ply epitaxial film consisting of the NiSi₂ layer 52, the Rh layer 58 and the Sr(Ti_{0.8}Nb_{0.2})O₃ layer 55.

By means of X-ray diffraction, it was confirmed that all of NiSi₂, Rh, Sr(Ti_{0.8}Nb_{0.2})O₃, and BTO were epitaxially grown at the (001) orientation relative to the surface of substrate. As for the relationship of in-plane orientation, however, it was constituted by: Si<100>//NiSi₂<100>//Rh<110>//Sr(Ti_{0.8}Nb_{0.2})O₃<110>//BT O<110>//Sr(Ti_{0.8}Nb_{0.2})O₃<110>. Namely, the layers after Rh were orientated relative to the Si substrate by an angle of 45 degrees (in-plane rotation). Further, the length of c-axis of the BTO layer was 0.430 nm which was about 8% longer than the length of c-axis of bulk BTO crystal, indicating that the length of c-axis was greatly elongated as compared with Comparative Embodiment. Further, when the half width was measured by measuring the rocking curve of the (002) peak of each layer thus grown, the half width in the case of the NiSi₂ layer 52 was 0.2°, the half width in the case of the Rh layer 58 was 0.30, the half width in the case of the Sr(Ti_{0.8}Nb_{0.2})O₃ layer 55 was 0.50, and the half width in the case of the BTO layer 56 was 0.5°, indicating that the crystallinity was greatly improved as compared with Comparative Embodiment.

Next, this laminated layer was patterned by means of lithography and dry etching techniques until the etching was proceeded up to the Si substrate, thereby forming capacitors having sizes ranging from 1 μm square to 100 μm square. When the length of c-axis of the BTO layer 56 was measured, the reduction in the length of c-axis due to the alleviation of the strain where the size of the capacitor was reduced, was found minimal as shown in FIG. 2, i.e. the length was 0.426 even when the size was 1 μm square, indicating that the length of c-axis was sufficiently extended as compared with the value of bulk crystal.

As explained above, in the structure of the capacitor which was manufactured by directly forming an NiSi₂ film 52, i.e. a film of lattice matching type metal on an Si substrate constituted by a semiconductor, thus forming an epitaxial film of excellent crystallinity, and then, an Rh/Sr/Sr(Ti_{0.8}Nb_{0.2})O₃/BTO/Sr(Ti_{0.8}Nb_{0.2})O₃ structure which can be aligned with through an in-plane rotation by an angle of 45 degrees is laminated on the epitaxial film, it is possible to obtain a dielectric film of excellent crystallinity, and also to expect, even if the size of capacitor is miniaturized, a sufficiently excellent ferroelectric property without alleviating the strain that has been introduced into the BTO capacitor.

(Embodiment 4)

Next, an FRAM representing one embodiment of the semiconductor memory element that can be manufactured through a combination of the epitaxial capacitor according to the present invention with a transistor will be explained.

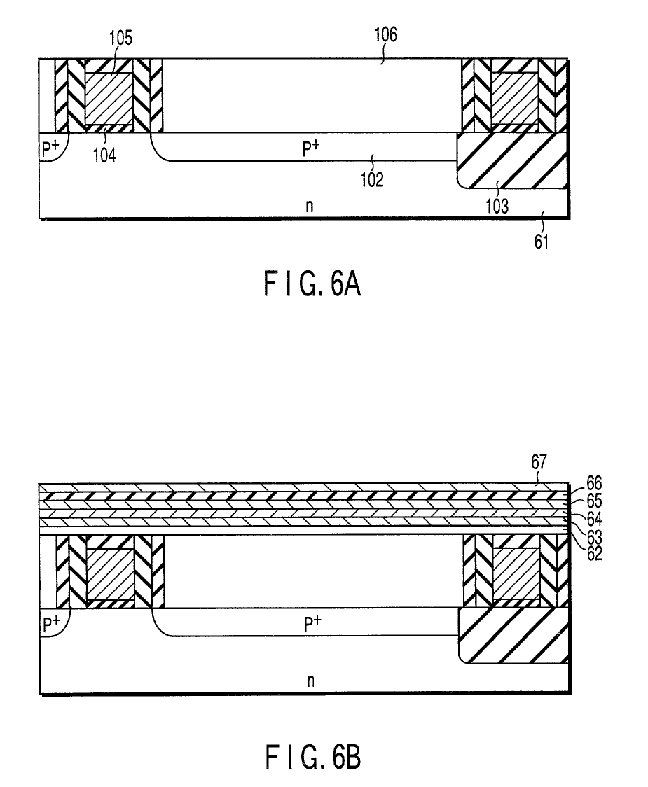

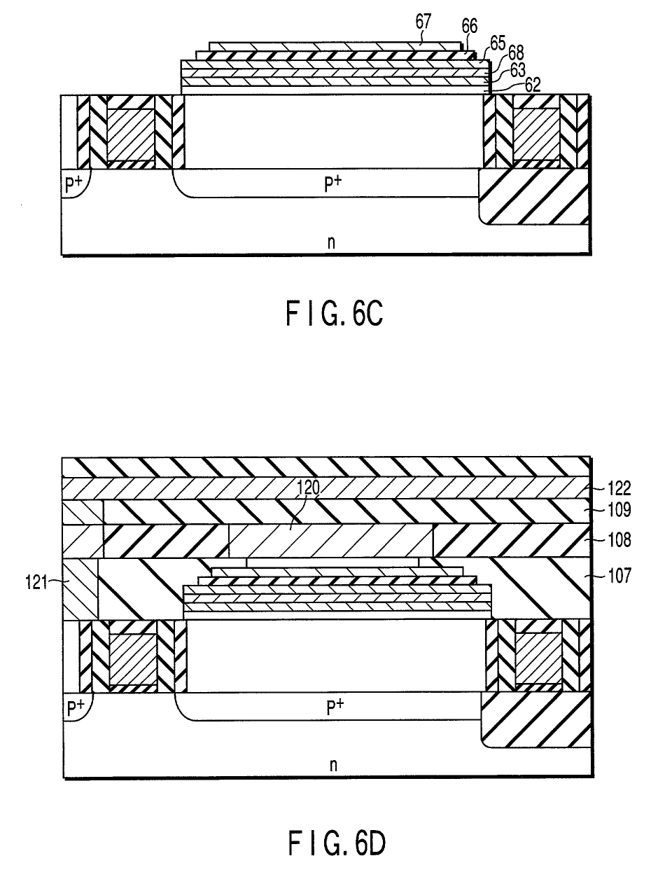

FIGS. 6A to 6D illustrate respectively a cross-sectional view illustrating the manufacturing steps of an FRAM memory cell according to a fourth embodiment of the present invention. Referring to these FIGS., the reference numeral 61 represents an n-type Si substrate; 102, a p-type impurity diffusion layer; 103, an element isolation insulating film; 104, a gate oxide film; 105, a word line; 106, a single crystal Si epitaxial growth layer; 107, 108 and 109, an insulating film; 62, a CoSi₂ layer; 63, a (Ti, Al)N layer; 68, an Ir layer; 65, an SRO layer; 66, a BTO dielectric thin film; 67, an SRO upper electrode; 120, a plate electrode; 121, a bit line contact; and 122, a bit line.

FIG. 6A shows a structure which was obtained after a processing wherein a transistor portion of memory cell was formed at first by the conventional steps, and then, a selective epitaxial growth of the single crystal Si layer 106 was performed, the single crystal Si layer 106 thus formed being subsequently flattened by means of chemical-mechanical polishing (CMP) method. In this case, a silicon oxide film was employed as an insulating film for insulating the word line 105. Further, with a view to remove any damaged layer that was formed on each portion of the surface of Si substrate in an RIE step, an etching was performed on the Si substrate by making use of hydrogen fluoride vapor, and then, the resultant Si substrate was transferred as it was in vacuum to a CVD chamber, in which a selective epitaxial growth was performed at a temperature of 750° C. using SiH₄ gas of 133 Pa (pressure) and AsH₃ gas of 13.3 Pa which was added as a donor.

Then, as shown in FIG. 6B, after an etching was performed using hydrogen fluoride vapor for the purpose of removing any damaged layer that was formed on the surface of the single crystal Si layer 106 in the CMP step, the CoSi₂ layer 62 was formed by means of a reactive sputtering method at a temperature of 600° C. Thereafter, the (Ti, Al)N layer 63 was formed by means of a reactive sputtering method by making use of a Ti—Al alloy target in an Ar/N₂ gas atmosphere and at a temperature of 600° C. Then, the Ir layer 68 was formed by means of a sputtering method at a temperature of 600° C. Furthermore, the SRO layer 65 was then formed to a thickness of 50 nm by means of a sputtering method using a ceramic target at a temperature of 600° C. As a result, the lower electrode having a 4-ply epitaxial structure was formed.

Thereafter, the BTO layer 66 as a ferroelectric thin film was formed to a thickness of 40 nm by means of a sputtering method using a ceramic target at a temperature of 600° C. Then, the SRO layer 67 as an upper electrode was formed to a thickness of 50 nm by means of a sputtering method using a ceramic target at a temperature of 600° C. In this case, all of CoSi₂ layer 62, (Ti, Al)N layer 63, Ir layer 68, SRO layer 65, BTO ferroelectric thin film 66 and SRO layer 67 were epitaxially grown in the form of single crystal on the single crystal Si layer 106. On the insulating film of the word line 105 however, all of these layers were grown in the form of polycrystal.

Then, as shown in FIG. 6C, the patterning of the SRO layer 67 was performed by means of the conventional lithography and RIE method, and then, the patterning of the BTO ferroelectric thin film 66 was performed, after which the patterning of CoSi₂ layer 62, (Ti, Al)N layer 63, Ir layer 68 and SRO layer 65 was collectively performed.

Thereafter, as shown in FIG. 6D, the silicon oxide insulating film 107 was buried inside the groove formed by the patterning by means of a plasma CVD method using TEOS as a raw material gas, and then, the resultant surface was flattened by way of a CMP method. Then, by means of the conventional patterning and film-forming methods, the plate electrode 120, the bit line contact 121, the bit line 122 and the silicon oxide insulating films 108 and 109 were formed.

When the orientations of these films thus formed were measured by making use of X-ray diffraction apparatus, it was confirmed that all of CoSi₂ layer 62, (Ti, Al)N layer 63, Ir layer 68, SRO layer 65, BTO ferroelectric thin film 66 and SRO layer 67 were all epitaxially grown at the (001) orientation. Further, the lattice constant in the thickness-wise direction of the BTO film 66 was found extended as large as 0.434 nm. Further, when the dielectric property of the ferroelectric thin film capacitor thus formed was measured, a large remanent polarization value of 55 μC/cm² could be obtained, thus confirming the capability thereof as a ferroelectric capacitor. Further, by way of the capacitor employing this ferroelectric thin film, the operation of the FRAM could be confirmed.

By the way, the present invention should not be construed as being limited to the aforementioned embodiments. For example, although the BTO was employed as a dielectric material of perovskite structure in the above embodiments, it is possible to employ various kinds of material. More specifically, in the composition represented by ABO₃, A may be mainly constituted by Ba, and part of Ba may be substituted by at least one kind of elements selected from Sr and Ca. Further, B may be selected from Ti, Sn, Zr, Hf, a solid solution thereof. Alternatively, B may be selected from composite oxides such as Mg_{⅓}, Ta_{⅔}, Nb_{⅔}, Zn_{⅓}, Nb_{⅔}, Zn_{⅔} and Ta_{⅔}, or a solid solution thereof.

As for the material for the perovskite type conductive oxide film to be employed for the lower electrode, it is not confined to the SRO, but it may be strontium molybdate or strontium titanate. Additionally, these strontium molybdate and strontium titanate may be partially substituted by niobium or lanthanum. Furthermore, the perovskite type conductive oxide film may be an oxide represented by a general formula ABO_{3-δ} (however, 0≦δ<1), wherein A is at least one kind selected from the group consisting of alkaline earth metals, rare earth metals and vacancy defect; and B is a transition metal.

As for the material for the nitride film to be employed for the lower electrode, it is not confined to (Ti, Al)N, but may be TiN or a substituted TiN wherein part of Ti is substituted by at least one kind of metals selected from the group consisting of Al, V, Mo, Nb and Ta.

As for the Ir layer to be employed for the lower electrode, part of Ir may be substituted by at least one kind of metals selected from the group consisting of Re, Ru, Os, Pt, Pd and Rh. Likewise, the Rh layer to be employed for the lower electrode, part of Rh may be substituted by at least one kind of metals selected from the group consisting of Re, Ru, Os, Pt, Pd and Ir.

With respect to other features also, the present invention can be variously modified and executed within the scope of claims accompanying herewith.

As explained above, according to the present invention, since the lower electrode of capacitor is constituted by; a 2-ply epitaxial film comprising a metal film containing Ir or Rh on the Si substrate, and a conductive oxide film having a perovskite crystal structure formed on the metal film; a 3-ply epitaxial film comprising a nitride film formed on the Si substrate, a metal film containing Ir or Rh and formed on the nitride film, and a conductive oxide film having a perovskite crystal structure and formed on the metal film; a 4-ply epitaxial film comprising a silicide film represented by a chemical formula MSi₂ (wherein M is at least one kind of transition metal selected from the group consisting of nickel, cobalt and manganese) and formed on the Si substrate, a nitride film formed on the silicide film, a metal film containing Ir or Rh and formed on the nitride film, and a conductive oxide film having a perovskite crystal structure and formed on the metal film; or a 3-ply epitaxial film comprising a silicide film represented by a chemical formula MSi₂ (wherein M is at least one kind of transition metal selected from the group consisting of nickel, cobalt and manganese) and formed on the Si substrate, a metal film containing Ir or Rh and formed on the silicide film, and a conductive oxide film having a perovskite crystal structure and formed on the metal film; it is possible to form a ferroelectric capacitor which is excellent in dielectric property and in reliability on a silicon substrate. As a result, it becomes possible to realize an FRAM of ultra-high integration, which is excellent in reliability. Therefore, the present invention would be very valuable in industrial view point.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A ferroelectric capacitor comprising;
an Si substrate;
a lower electrode including a metal film containing Ir or Rh and epitaxially grown on the Si substrate, and a conductive oxide film having a perovskite crystal structure and epitaxially grown on the metal film;
a perovskite type ferroelectric thin film epitaxially grown on the lower electrode; and
an upper electrode formed on the ferroelectric thin film.

2. The ferroelectric capacitor according to claim 1, wherein said metal film is formed of an alloy having an fcc structure and comprising Ir, and at least one kind of metals selected from the group consisting of Re, Ru, Os, Pt, Pd and Rh.

3. The ferroelectric capacitor according to claim 1, wherein said metal film is formed of an alloy having an fcc structure and comprising Rh, and at least one kind of metals selected from the group consisting of Re, Ru, Os, Pt, Pd and Ir.

4. The ferroelectric capacitor according to claim 1, wherein said conductive oxide film is formed of an oxide represented by a general formula ABO_{3-δ} (wherein A is at least one kind selected from the group consisting of alkaline earth metals, rare earth metals and vacancy defect; B is a transition metal; and δ is 0≦δ<1).

5. The ferroelectric capacitor according to claim 1, wherein said metal film has a thickness ranging from 10 to 50 nm, and said conductive oxide film has a thickness ranging from 10 to 50 nm.

6. The ferroelectric capacitor according to claim 1, wherein a nitride film is interposed between said Si substrate and said metal film.

7. The ferroelectric capacitor according to claim 6, wherein said nitride film is formed of TiN or a substituted TiN wherein part of Ti is substituted by at least one kind of metals selected from the group consisting of Al, V, Mo, Nb and Ta.

8. The ferroelectric capacitor according to claim 6, wherein said nitride film has a thickness ranging from 5 to 30 nm.

9. The ferroelectric capacitor according to claim 6, wherein a silicide film represented by a chemical formula MSi₂ (wherein M is at least one kind of transition metal selected from the group consisting of nickel, cobalt and manganese) is interposed between said Si substrate and said nitride film.

10. The ferroelectric capacitor according to claim 9, wherein said silicide film has a thickness ranging from 5 to 30 nm.

11. The ferroelectric capacitor according to claim 1, wherein said ferroelectric thin film is formed of a ferroelectric substance having a perovskite crystal structure and represented by a chemical formula ABO₃ (wherein A is at least one kind selected from the group consisting of Ba, Sr and Ca; and B is at least one kind selected from the group consisting of Ti, Zr, Hf and Sn).

12. The ferroelectric capacitor according to claim 1, wherein said ferroelectric thin film is featured in that the length Ce of c-axis after an epitaxial growth and the length Co of c-axis inherent to the tetragonal system or of a-axis inherent to the cubic system before the epitaxial growth and corresponding to said c-axis Ce meet the following formula:
Ce/Co≧1.02

13. A ferroelectric capacitor comprising;
an Si substrate;
a lower electrode including a silicide film represented by a chemical formula MSi₂ (wherein M is at least one kind of transition metal selected from the group consisting of nickel, cobalt and manganese) and epitaxially grown on the Si substrate, a metal film containing Ir or Rh and epitaxially grown on the silicide film, and a conductive oxide film having a perovskite crystal structure and epitaxially grown on the metal film;
a perovskite type ferroelectric thin film epitaxially grown on the lower electrode; and
an upper electrode formed on the ferroelectric thin film.

14. The ferroelectric capacitor according to claim 13, wherein said metal film is formed of an alloy having an fcc structure and comprising Ir, and at least one kind of metals selected from the group consisting of Re, Ru, Os, Pt, Pd and Rh.

15. The ferroelectric capacitor according to claim 13, wherein said metal film is formed of an alloy having an fcc structure and comprising Rh, and at least one kind of metals selected from the group consisting of Re, Ru, Os, Pt, Pd and Ir.

16. The ferroelectric capacitor according to claim 13, wherein said conductive oxide film is formed of an oxide represented by a general formula ABO_{3-δ} (wherein A is at least one kind selected from the group consisting of alkaline earth metals, rare earth metals and vacancy defect; B is a transition metal; and δ is 0≦δ<1).

17. The ferroelectric capacitor according to claim 13, wherein said silicide film has a thickness ranging from 5 to 30 nm, said metal film has a thickness ranging from 10 to 50 nm, and said conductive oxide film has a thickness ranging from 10 to 50 nm.

18. The ferroelectric capacitor according to claim 13, wherein said ferroelectric thin film is formed of a ferroelectric substance having a perovskite crystal structure and represented by a chemical formula ABO₃ (wherein A is at least one kind selected from the group consisting of Ba, Sr and Ca; and B is at least one kind selected from the group consisting of Ti, Zr, Hf and Sn).

19. The ferroelectric capacitor according to claim 13, wherein said ferroelectric thin film is featured in that the length Ce of c-axis after an epitaxial growth and the length Co of c-axis inherent to the tetragonal system or of a-axis inherent to the cubic system before the epitaxial growth and corresponding to said c-axis Ce meet the following formula:
Ce/Co≧1.02

20. A semiconductor device comprising;
an Si substrate;
a MOS type transistor formed on the Si substrate; and
a ferroelectric capacitor formed on the Si substrate and connected with the MOS type transistor;
wherein said ferroelectric capacitor comprises;
a lower electrode including a metal film containing Ir or Rh and epitaxially grown on the Si substrate, and a conductive oxide film having a perovskite crystal structure and epitaxially grown on the metal film;
a perovskite type ferroelectric thin film epitaxially grown on the lower electrode; and
an upper electrode formed on the ferroelectric thin film.
